(19) United States
(12) Patent Application Publication
(10) Pub. No.: US 2025/0087269 A1
(43) Pub. Date: Mar. 13, 2025

(54) Non-volatile Memory Device

(71) Applicant: AMIC Technology Corporation, Hsin-Chu City (TW)

(72) Inventors: Chun-Hao Huang, Kaohsiung City (TW); Hsiao-Hua Lu, Hsinchu County (TW); Yung-Tien Peng, Hsinchu City (TW)

(73) Assignee: AMIC Technology Corporation, Hsin-Chu City (TW)

(21) Appl. No.: 18/378,645

(22) Filed: Oct. 10, 2023

(30) Foreign Application Priority Data
Sep. 12, 2023 (TW) 112134694

(51) Int. Cl. G11C 16/04; G11C 16/10; G11C 16/16

(52) U.S. Cl. CPC G11C 16/0491; G11C 16/0483; G11C 16/10; G11C 16/16

(57) ABSTRACT

A non-volatile memory device comprises at least one non-volatile memory cell, electrically connected to at least one bit line, a first select line, a second select line, a control line and a common line. Each non-volatile memory cell comprises a first select transistor, having a drain electrically connected to a bit line, and a gate electrically connected to the first select line; a second select transistor, having a source electrically connected to the common line, and a gate electrically connected to the second select line; and a transistor with a floating gate, having a drain electrically connected to a source of the first select transistor, a gate electrically connected to the control line, and a source electrically connected to a drain of the second select transistor; wherein when performing erase or write operation, the second select line is grounded, causing the second select transistor to turn off.

### BACKGROUND OF THE INVENTION

### 1. Field of the Invention

The present invention relates to a non-volatile memory device, and more particularly, to a non-volatile memory device capable of reducing circuit area, power consumption, and layout complexity, while increasing the overall number of operations.

### 2. Description of the Prior Art

Non-volatile memory is a type of storage device that can store data without power supply. Common non-volatile memory includes magnetic storage devices, optical discs, flash memory and other semiconductor-based memory forms. Generally speaking, non-volatile memory is often manufactured by logic complementary metal oxide semiconductor (CMOS) process, and each non-volatile memory unit in the non-volatile memory is manufactured to execute read, program and erase modes.

For example, please refer to FIG. 1, which is a schematic diagram of a non-volatile memory device 10 disclosed in U.S. Pat. No. 5,430,675A. The non-volatile memory device 10 corresponds to a page or a part of a page (byte), which includes a page selection transistor PG, control transistors MS1 to MSn, MG1 to MGn, and transistors with floating gates (hereinafter referred to as floating gate transistors) MT1 to MTn. As shown in FIG. 1, the control transistors MS1 to MSn, the floating gate transistors MT1 to MTn and the control transistors MG1 to MGn are respectively connected in series between bit lines BL1 to BLn and a ground GND, and are controlled by the word line WL and the control line CL to store the states of the bit lines BL1 to BLn; and the page selection transistor PG determines whether to operate the non-volatile memory device 10 according to the page line PL and the word line WL.

In detail, when the system needs to delete data from or write data to the page corresponding to the non-volatile memory device 10, the non-volatile memory device 10 needs to perform an erase operation. When performing the erase operation, the voltages of the selected word line WL, page line PL and bit lines BL1 to BLn are respectively set to a first high voltage, a second high voltage and a low voltage, and the sources S of the floating gate transistors MT1 to MTn are in an open state. Under this condition, according to the voltage of the page line PL, the voltages of the gates G of the floating gate transistors MT1 to MTn become high; according to the voltages of the bit lines BL1 to BLn, the voltages of the drains D of the floating gate transistors MT1 to MTn become low. Due to the electric field generated between the gate G and the drain D of each of the floating gate transistors MT1 to MTn, the electrons at the drain D of each of the floating gate transistors MT1 to MTn tunnel to the floating gate. In this way, the threshold voltages of all the floating gate transistors MT1 to MTn will increase. At the same time, by setting the voltages of the bit lines BL1 to BLn to a low voltage, the threshold voltages of all the transistors will also increase, thereby placing the non-volatile memory device 10 in an erased state.

It should be noted that during the erase operation, in order to turn on the page selection transistor PG, the voltage of the word line WL must be at least one threshold voltage higher than the page line PL; that is, the first high voltage must be at least one threshold voltage higher than the second high voltage. Only in this way can the high voltage of the page line PL be transmitted from the drain D of the page selection transistor PG to the gates G of the floating gate transistors MT1 to MTn, thereby grounding the bit lines BL1 to BLn, and using the voltage difference between the page line PL and the bit lines BL1 to BLn to let electrons tunnel into the floating gate.

On the other hand, to perform a write operation, the erase operation described above must be performed first. When the selected page completes the erase operation and is ready to perform the write operation, the page line PL is grounded, the gate word line WL of the page selection transistor PG is given a highest voltage (the first high voltage), and the bit lines BL1 to BLn are given a secondary high voltage (the second high voltage) or grounded. The electrons are driven out of the floating gate by using the voltage difference between the page line PL and the bit lines BL1 to BLn, thereby reducing the threshold voltages of the floating gate transistors MT1 to MTn, and thus completing the write operation.

As can be seen from the above, each page composed of the non-volatile memory device 10 requires at least one page selection transistor PG, and the number of the page selection transistors PG depends on how many bytes are contained in one page. Since the page selection transistor PG needs to supply voltage of the page line PL to all the floating gate transistors MT1 to MTn in the page, the page selection transistor PG needs a certain size to meet the driving capability requirements. Under this circumstance, the page selection transistors PG in all pages will occupy a lot of area and increase the complexity of circuit layout.

Furthermore, the page line PL needs to be given the highest voltage during the erase operation, and the word line WL needs to be given at least one threshold voltage higher than the page line PL (the page selection transistor PG) to turn on the page selection transistor PG. In other words, the system needs to prepare an even higher voltage to turn on the page selection transistor PG, so the high voltage pump needs more stages to generate a higher voltage, which will increase its circuit area and power consumption.

Therefore, how to reduce the circuit area, circuit layout complexity and power consumption of non-volatile memory becomes one of the goals that the industry strives for.

### SUMMARY OF THE INVENTION

Therefore, the present invention is to provide a non-volatile memory device to improve the drawbacks of the prior art.

An embodiment of the present invention discloses a non-volatile memory device, comprising at least one non-volatile memory cell, electrically connected to at least one bit line, a first select line, a second select line, a control line and a common line. Each of the at least one non-volatile memory cell comprises a first select transistor, having a drain electrically connected to one of the at least one bit line, and a gate electrically connected to the first select line; a second select transistor, having a source electrically connected to the common line, and a gate electrically connected to the second select line; and a transistor with a floating gate, having a drain electrically connected to a source of the first select transistor, a gate electrically connected to the control line, and a source electrically connected to a drain of the second select transistor; wherein when performing an erase operation or a write operation on the non-volatile memory device, the second select line is grounded, causing the second select transistor to turn off.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a non-volatile memory device of the prior art.

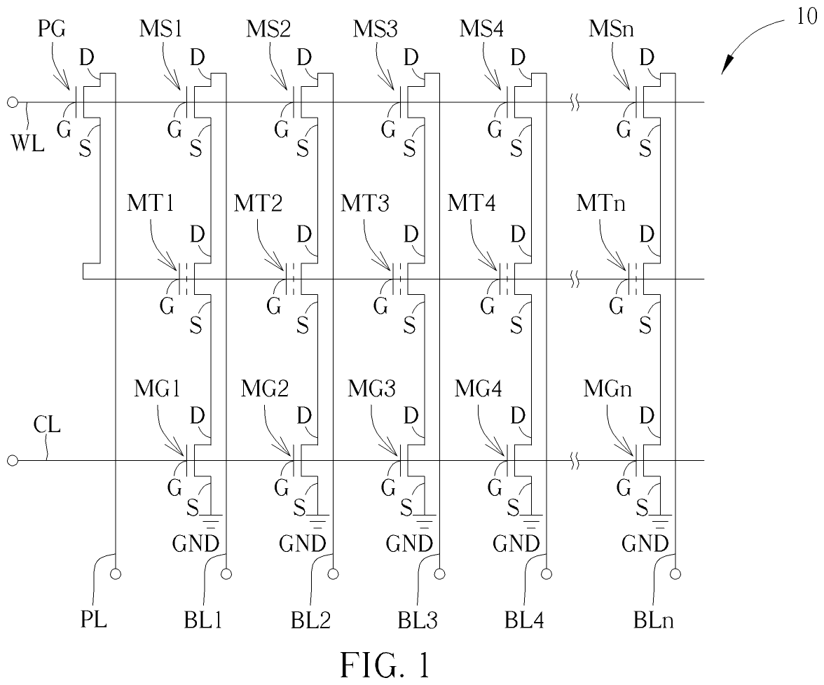

FIG. 2 is a schematic diagram of a non-volatile memory device according to an embodiment of the present invention.

FIG. 3 is a schematic diagram of an example of data changes when performing a write operation on the non-volatile memory device of FIG. 2.

FIG. 4 is a schematic diagram of a storage device according to an embodiment of the present invention.

### DETAILED DESCRIPTION

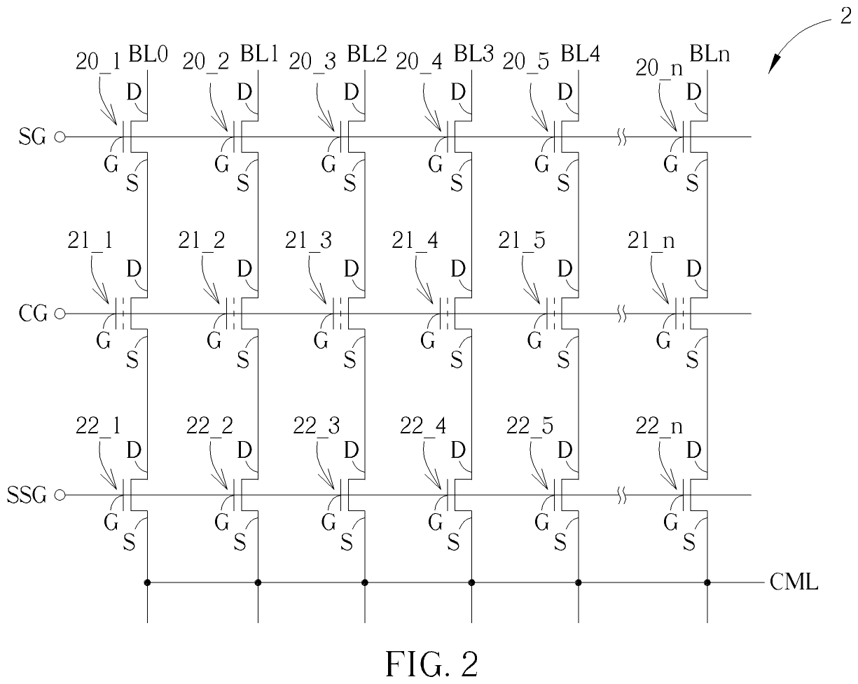

Please refer to FIG. 2, which is a schematic diagram of a non-volatile memory device 2 according to an embodiment of the present invention. The non-volatile memory device 2 corresponds to a page or a part of a page (byte), which includes first selection transistors 20_1 to 20_n, second selection transistors 22_1 to 22_n and transistors with floating gates (hereinafter referred to as floating gate transistors) 21_1 to 21_n. In other words, the non-volatile memory device 2 does not include a page selection transistor. The first selection transistors 20_1 to 20_n, the floating gate transistors 21_1 to 21_n and the second selection transistors 22_1 to 22_n are respectively connected in series to form n memory cells corresponding to n bits, and each memory cell is electrically connected between one bit line of bit lines BL_1 to BL_n and a common line CML, and the common line CML is preferably grounded. In detail, the drain D of any first selection transistor 20_x is electrically connected to a corresponding bit line BL_x, the source S of the first selection transistor 20_x is electrically connected to the drain D of the corresponding floating gate transistor 21_x, the source S of the floating gate transistor 21_x is electrically connected to the drain D of the corresponding second selection transistor 22_x, and the source S of the second selection transistor 22_x is electrically connected to the common line CML. In addition, the gates G of the first selection transistors 20_1 to 20_n are electrically connected to a first select line SG, the gates G of the second selection transistors 22_1 to 22_n are electrically connected to a second select line SSG, and the gates G of the floating gate transistors 21_1 to 21_n are electrically connected to a control line CG. By properly controlling the levels of the first select line SG, the second select line SSG and the control line CG, the non-volatile memory device 2 can be controlled to perform read, program and erase operations.

In short, the non-volatile memory device 2 does not require a page selection transistor, and can perform erase and write operations by properly controlling the first select line SG, the second select line SSG and the control line CG. This can reduce the circuit area, circuit layout complexity and power consumption. In addition, the non-volatile memory device 2 of the present invention can reduce the number of bit data changes in the whole system, thereby having a higher number of operations, and this number of operations will not decrease with the increase of the number of bytes in a page. The non-volatile memory device of the present invention also has the ability to perform single-byte operations of electrically erasable programmable read-only memory (EEPROM). The operating principle of the non-volatile memory device is explained below.

First, when the page corresponding to the non-volatile memory device 2 is selected to perform an erase operation, if some bytes (including multiple bits) need to be erased, and some bytes do not need to be erased, at this time, the system should provide a ground voltage on the second select line SSG to turn off the second selection transistors 22_1 to 22_n, thereby disconnecting the paths between the bit lines BL0 to BLn and the common line CML, and allowing the bit lines BL0 to BLn to be independent of each other. After the bit lines BL0 to BLn are independent of each other, the system should first read out the previous data, for example, to store the data in a register (such as a page buffer) according to its address, so that the bit lines corresponding to the bytes that do not need to be erased can be given high voltage or grounded according to the data in the register. Then, the second select line SSG remains grounded, and the system should provide the highest voltage (for example, HV1) on the first select line SG and the control line CG. At this time, the bit lines BL0 to BLn corresponding to the addresses that need to be erased should be set to ground. Because of the voltage difference between the control line CG and the bit lines corresponding to the addresses that need to be erased, electrons are attracted by the highest voltage of the control line CG and tunnel into the floating gate of the corresponding floating gate transistor, completing the erase operation; and the bit lines of bytes that do not need to be erased are the same as the previous data, that is, the addresses with secondary high voltage (for example, HV2) in the bit lines BL0 to BLn (that is, addresses that do not need to be erased) do not have enough voltage difference with the control line CG and will not produce any tunneling action, such that there is no change in the floating gate of its corresponding floating gate transistor. In other words, during erasure, only addresses that need to be erased will be erased (to have electrons tunnel into their corresponding floating gates), and addresses that do not need to be erased will not change at all, thereby reducing the number of data changes and thus having a higher number of operations.

On the other hand, when the page corresponding to the non-volatile memory device 2 is selected to perform a write operation, if some bytes have data to be written, and some bytes do not have data to be written, at this time, the system should also provide a ground voltage on the second select line SSG to turn off the second selection transistors 22_1 to 22_n, allowing each bit line BL0 to BLn to be independent. After the bit lines BL0 to BLn are independent of each other, the system should first read out the previous data and store it in a register (such as a page buffer) according to its address, and then store the data to be written in the register according to its address. At this time, the signal of the data to be written is stronger and will replace the data at the corresponding address in the register, while the address that does not need to write data is the same as the data in the non-volatile memory device 2. After data fetching and temporary storage are completed, an erase operation must be performed first; that is, the second select line SSG remains grounded, and the system should provide the highest voltage (for example, HV1) on the first select line SG and control line CG. At this time, bit lines BL0 to BLn that are grounded (that is, addresses corresponding to erasure) will have their electrons attracted by the highest voltage of the control line CG and tunnel into floating gates of the corresponding floating gate transistors to complete erasure operation; while the bit lines BL0 to BLn with secondary high voltage (for example, HV2) (that is, addresses that do not need erasure) will not produce any tunneling action due to insufficient voltage difference with the control line CG, so there is no change in floating gates of the corresponding floating gate transistors. After completing the erase operation, when performing writing, the system should provide the highest voltage (for example, HV1) on the first select line SG and ground the control line CG. The voltages of the bit lines BL0 to BLn are related to the data in the register. If the data in the register is 0, then bit line corresponding to that address will be grounded. If the data in the register is 1, then bit line corresponding to that address will be given high voltage (for example, HV2). Under this circumstance, bit lines that are grounded within the bit lines BL0 to BLn will not produce any tunneling action because there is no voltage difference with the control line CG, so there is no change in floating gates of the corresponding floating gate transistors; while bit lines with secondary high voltage (for example HV2) within the bit lines BL0 to BLn will have enough voltage difference with the control line CG, so that electrons inside floating gates of the corresponding floating gate transistors will be attracted by the secondary high voltage of the bit lines and tunnel out of the floating gates, thus completing write operation. In other words, during writing operation, only addresses that need to be written will be erased and then written with data; addresses that do not need to write data will not perform erase and rewrite procedures and will not change at all. This can reduce overall number of data changes and thus have a higher number of operations.

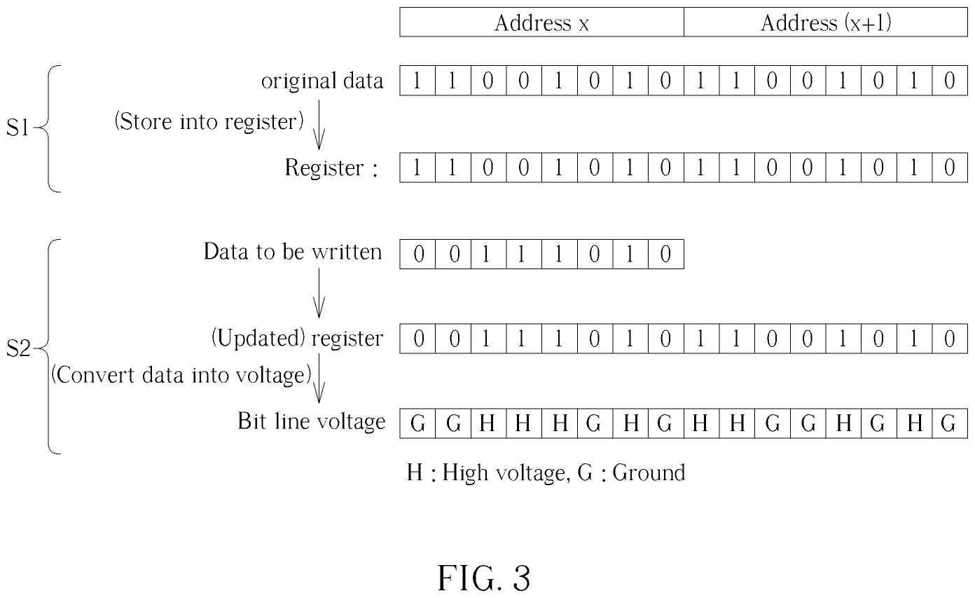

To illustrate the above data processing method, please refer to FIG. 3, which is a schematic diagram of an embodiment of data changes when the non-volatile memory device 2 performs a write operation. For simplicity, FIG. 3 only shows the bytes at addresses x and (x+1) in the non-volatile memory device 2 as representatives, and there is data to be written to the byte at address x, and no data to be written to the byte at address (x+1). Assume that the original byte data at addresses x and (x+1) are both (1 1 0 0 1 0 1 0), and the data to be written to address x is (0 0 1 1 1 0 1 0). First, in stage S1, the system provides a ground voltage on the second select line SSG to make each of the bit lines BL0 to BLn independent, and reads out the original data and stores it in a register (such as a page buffer) according to its address. Then, in stage S2, the data (0 0 1 1 1 0 1 0) to be written to address x is stored in the register, and replaces the data at the corresponding address x in the register because its signal is stronger, while there is no data to be written to address (x+1), so the original data is still maintained in the register. At this stage, the system performs an erase operation on address x first. After completing the erase operation, when performing writing, the data in the register is set to ground (marked as L) for bit lines corresponding to data of 0, and set to high voltage (marked as H) for bit lines corresponding to data of 1, thereby completing the write operation. It can be seen that in this example, because only address x has data to be written, only the memory cell corresponding to address x will be erased and then written with data, while addresses that do not need to write data will not perform erase and rewrite procedures and will not change at all. This can reduce the number of data changes and thus have a higher number of operations. It should be noted that FIG. 3 is only an example of illustrating how the non-volatile memory device 2 performs data changes and adjusts bit line voltages when performing write operations. Those skilled in the art can adjust it appropriately according to system requirements without being limited thereto.

As can be seen from the above, when the non-volatile memory device 2 performs erase or write operations, by grounding the second select line SSG, the second selection transistors 22_1 to 22_n can be turned off, allowing each of the bit lines BL0 to BLn to be independent, so that the bit lines corresponding to each byte can be independently controlled. In this way, only the bytes that need to be erased or written can be erased or written, and the data of the bytes that do not need to be erased or written will not change. In this case, it can reduce the number of changes in each byte of data, and overall, it can increase the number of operations, and this number of operations will not decrease with the increase in the number of bytes in a page. At the same time, because each byte corresponding to the bit line can be independently controlled, the non-volatile memory device 2 can have a single-byte operation capability similar to electrically erasable programmable read-only memory. Furthermore, because the non-volatile memory device 2 does not contain a page selection transistor and does not need to use a low-threshold voltage transistor or prepare an extra high voltage to turn on the page selection transistor, it can reduce circuit area, circuit layout complexity and power consumption.

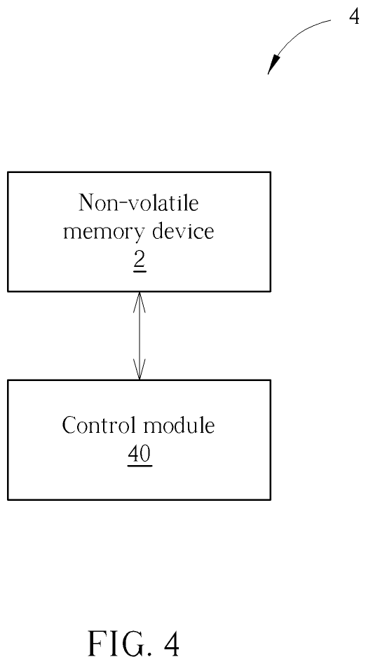

In addition, the non-volatile memory device 2 is an embodiment of this invention. Those skilled in the art can make different changes based on this without being limited thereto. For example, please refer to FIG. 4, which is a schematic diagram of a storage device 4 according to an embodiment of the present invention. The storage device 4 includes a control module 40 and one or more (one as an example) non-volatile memory devices 2. The control module 40 is used to control the one or more non-volatile memory devices 2. The control module 40 preferably includes one or more decoders, one or more registers (such as page buffers), and one or more high voltage pumps; where decoders can decode the non-volatile memory devices 2 to read out data and temporarily store it in registers; while registers not only temporarily store data in the non-volatile memory devices 2 but also receive data to be written, and data to be written with stronger signals will replace data at corresponding addresses in registers; the high voltage pumps can generate aforementioned highest voltage HV1, secondary high voltage HV2 and ground voltage, and output them to the first select line SG, the second select line SSG and the control line CG according to system control to control the non-volatile memory devices 2 for read, write and erase operations. That is to say, when a non-volatile memory device 2 is selected for erase or write operations, the high voltage pump provides ground voltage on the second select line SSG so that each of the bit lines BL0 to BLn is independent, and the decoders read out previous data and temporarily store it in registers according to its address; at this time, if it is a write operation, data to be written will replace data at corresponding address in register. Then, erase operation is executed, the high voltage pump provides the highest voltage HV1 on the first select line SG and the control line CG while maintaining ground voltage on the second select line SSG; since the bit lines BL0 to BLn are independent of each other, only addresses that need erasure will be erased while addresses that do not need erasure will not change at all. If writing operation needs to be performed after erasure operation is completed, the high voltage pump provides the highest voltage HV1 on the first select line SG and ground voltage on the control line CG while maintaining ground voltage on the second select line SSG, and provides corresponding voltages on the bit lines BL0 to BLn according to data in register. Accordingly, the control module 40 may appropriately control the non-volatile memory device 2 to perform different operations according to system requirements.

Note that, the storage device 4 shown in FIG. 4 is an example of using the control module 40 with a single non-volatile memory device 2, but is not limited thereto. In other embodiments, it can also be a single control module 40 controlling multiple non-volatile memory devices 2, which also falls within the scope of the present invention. Furthermore, the number of transistors or bit lines n in the non-volatile memory device 2 is related to the number of bits contained in the corresponding page, and can also be appropriately increased or decreased.

In the prior art, each page requires at least one page selection transistor, and the number of page selection transistors depends on how many bytes are contained in a page. Since the page selection transistor needs to supply the page line voltage to all floating gate transistors in the corresponding page, it requires a certain size to meet the driving capability requirements. In this case, all page selection transistors in all pages will occupy a lot of area and increase circuit layout complexity. Moreover, the page line needs to be given the highest voltage during erasure, and at this time, the word line needs to be given at least one threshold voltage higher than the page line to turn on the page selection transistor. Therefore, high voltage pumps need more stages to generate higher voltages, thereby increasing circuit area and power consumption.

In comparison, the non-volatile memory device of the present invention does not require a page selection transistor and does not need to prepare extra high voltage to turn on the page selection transistor, thereby reducing circuit area, power consumption and layout complexity. Moreover, the non-volatile memory device of the present invention can independently control bit lines corresponding to each byte when performing erase or write operations, thereby achieving a single-byte operation capability similar to electrically erasable programmable read-only memory. In this way, only bytes that need to be erased or written can be erased or written without changing data of bytes that do not need to be erased or written. As a result, the present invention can reduce number of changes in each byte of data and thus increase overall number of operations which will not decrease with increase in number of bytes in a page.

In summary, the non-volatile memory device of the present invention can reduce circuit area, power consumption and layout complexity while increasing overall number of operations, thereby greatly improving drawbacks of the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory device, comprising at least one non-volatile memory cell, electrically connected to at least one bit line, a first select line, a second select line, a control line and a common line, each of the at least one non-volatile memory cell comprising:
a first select transistor, having a drain electrically connected to one of the at least one bit line, and a gate electrically connected to the first select line;
a second select transistor, having a source electrically connected to the common line, and a gate electrically connected to the second select line; and
a transistor with a floating gate, having a drain electrically connected to a source of the first select transistor, a gate electrically connected to the control line, and a source electrically connected to a drain of the second select transistor;
wherein when performing an erase operation or a write operation on the non-volatile memory device, the second select line is grounded, causing the second select transistor to turn off.

2. The non-volatile memory device of claim 1, which does not comprise a page select transistor.

3. The non-volatile memory device of claim 1, wherein when the second select transistor of each of the non-volatile memory cells is turned off, a path from the at least one bit line through the at least one non-volatile memory cell to the common line is turned off, making each of the at least one bit line independent.

4. The non-volatile memory device of claim 1, further electrically connected to a register, wherein the register is used to store data of the non-volatile memory device when performing the erase operation or the write operation on the non-volatile memory device.

5. The non-volatile memory device of claim 4, wherein when performing the write operation on the non-volatile memory device, the register is further used to replace the stored data of the non-volatile memory device with data to be written into the non-volatile memory device.

6. The non-volatile memory device of claim 5, wherein when performing the write operation on the non-volatile memory device, a voltage of each of the at least one bit line is related to data of the register.

7. The non-volatile memory device of claim 1, wherein when performing the erase operation on the non-volatile memory device, a high voltage is provided to the first select line and the control line.

8. The non-volatile memory device of claim 1, wherein when performing the write operation on the non-volatile memory device, a high voltage is provided to the first select line, and the control line is grounded.
